(19) United States
(12) Patent Application Publication
(10) Pub. No.: US 2013/0119000 A1
(43) Pub. Date: May 16, 2013

(54) Portable stand apparatus for an electronic display

(71) Applicant: Marty Joel Carty, Sunbury, OH (US)

(72) Inventor: Marty Joel Carty, Sunbury, OH (US)

(21) Appl. No.: 13/507,746

(22) Filed: Jul. 25, 2012

Related U.S. Application Data
(60) Provisional application No. 61/572,998, filed on Jul. 26, 2011.

(51) Int. Cl. H05K 7/18

(52) U.S. Cl. CPC H05K 7/18
USPC 211/26

(57) ABSTRACT

A portable mobile stand apparatus is provided for an electronic display unit, such as a flat screen television, and includes a base unit and a riser unit connected thereto. A support bracket assembly is interconnected between the electronic display unit and the riser unit. Preferably, the base unit and the riser unit include a sports theme, such as football. More preferably, the riser unit simulates football goal posts having a horizontal cross-bar and a pair of spaced uprights, which together provide an attractive eye-catching visual frame for the flat screen television display unit. The riser unit further includes adjustable portions such that the riser unit may be fitted to a display unit of selected size.

### CROSS-REFERENCE TO RELATED APPLICATION

This application claims priority based upon my co-pending Provisional Application Ser. No. 61/572,998, filed Jul. 26, 2011.

### BACKGROUND OF THE INVENTION

1. Field of the Invention

The present invention relates generally to stands for electronic display units, and, more particularly, to a portable stand apparatus especially adapted for electronic display units, such as flat screen televisions.

2. Description of the Prior Art

Generally, stands for electronic display units, such as flat screen televisions are well known in the art.

More specifically, first and foremost, the uses of flat screen televisions and computers have become more and more frequent. While this is true, consumers are limited to basic styles for their stands, wall mounts, and other devices used to house their screens. These flat screens and other electronic display units can also be very heavy and cumbersome to move and thus often placed as a stationary location (or mounting) within the residence or place of business. The thought of having the ability to transport the flat screens throughout the inside of said residence or business is quickly dismissed and to use flat screen devices to entertain in various rooms or the immediate outdoors is therefore deemed next to impossible. Add the fact that many owners of these flat screen entertainment pieces are sports fans, there becomes a frustration factor in not only being limited to portability, but also not having an option to decorate the environment with support for ones preferred sports team, person, or business on the current offerings of flat screen stands and/or wall mounts.

In view of the above, it would be desirable to provide a portable stand for electronic display units, such as flat screen televisions.

Also, in view of the above, it would be desirable to provide a portable stand apparatus for electronic display units that exhibits themes, such as sport themes, that are compatible with preferences of the viewers of the flat screen televisions.

As an example, it would be desirable to provide a portable stand apparatus for electronic display units that exhibits themes of preferred football teams of the viewers.

Thus, while the foregoing body of prior art indicates it to be well known to use stands for flat screen televisions, the stands described above do not teach or suggest a stand apparatus for a flat screen television which has the following combination of desirable features: (1) provides a portable stand for electronic display units, such as flat screen televisions; (2) exhibits themes, such as sport themes, that are compatible with preferences of the viewers of the flat screen televisions; (3) exhibits a “football” theme preferred by many viewers, and (4) provides a riser unit incorporated in the portable stand that simulates football goal posts characterized by a horizontal cross-bar and a pair of spaced uprights, which in turn provides an attractive eye-catching visual frame for the flat screen television display unit supported by the stand.

The foregoing desired characteristics are provided by the unique portable stand apparatus for an electronic display of the present invention as will be made apparent from the following description thereof. Other advantages of the present invention over the prior art also will be rendered evident.

### SUMMARY OF THE INVENTION

To achieve the foregoing and other advantages, the present invention, briefly described, provides a portable stand apparatus for an electronic display unit, such as a flat screen television, and includes a base unit and a riser unit connected thereto. Riser-to-base connection means are connected to and supported by the base unit. A support bracket assembly is interconnected between the electronic display unit and the riser unit. Preferably, the bottom of the base unit has wheel assemblies, and the support bracket assembly has handle members. The handle members and the wheel assemblies provide for easy portability and movability of the portable stand apparatus.

Preferably, the portable stand apparatus can include a sport theme, a business theme, or a branding theme.

The riser-to-base connection means include a riser-reception channel for receiving the bottom portion of the riser unit.

Preferably, the support bracket assembly includes a support bracket base member. A pair of base-member-to-display connector members are located on a first side of the support bracket base member and are in sliding engagement with the support bracket base member. A base-member-to-riser-unit connector assembly is connected to a second side of the support bracket base member, and a pair of handle members is connected to the second side of the support bracket base member. The support bracket base member includes a top portion which engages the base-member-to-display connector members for sliding engagement therewith.

Preferably, the riser unit includes a first vertical riser portion that is connected to and supported by the base unit. A horizontal riser portion is connected to a top portion of the first vertical riser portion. The horizontal riser portion extends from the first vertical riser portion toward a front side of the base unit. A second vertical riser portion is connected to the horizontal riser portion.

More specifically, the horizontal riser portion can be formed as a curved degree transition member which includes a horizontal portion, a horizontal-to-vertical bend portion, and a vertical portion. In this respect, the curved degree transition member can be welded to the first vertical riser portion.

The second vertical riser portion includes connection channels for permitting connection of the support bracket assembly to the second vertical riser portion by employing fasteners

The electronic display unit includes an electric power cord, and the second vertical riser portion includes a first cord-reception channel for receiving the electric power cord.

Preferably, the first vertical riser portion is connected to and supported by the base unit at an edge location in the base unit. The base unit includes an equipment storage chamber.

The base unit includes a second cord-reception channel for receiving the electric power cord.

The wheel assemblies that are connected to bottom portions of the base unit can include swivel caster wheel assemblies each of which includes wheel locks.

The base unit has a theme of a sport locker, and the base unit also includes locker-inspired vents. The base unit includes a selected sport theme. In this respect, the top portion of the base unit can include the selected sport theme thereon. The top portion of the base unit can include a football field theme.

The riser unit includes the selected sport theme. The selected sport theme can be a football theme. In this respect, the riser unit includes a center vertical football goal post theme.

A bottom horizontal goal post theme assembly is connected to the riser unit and includes a left vertical goal post theme assembly and a right vertical goal post theme assembly. Each has a vertical goal post theme that is connected to respective ends of the bottom horizontal goal post theme assembly.

More specifically, the bottom horizontal goal post theme assembly includes a central bottom horizontal goal post theme member. A left bottom horizontal goal post theme member is connected to a left end of the central bottom horizontal goal post theme member, and a right bottom horizontal goal post theme member is connected to a right end of the central bottom horizontal goal post theme member.

Preferably, there is a telescopic connection between the left bottom horizontal goal post theme member and the central bottom horizontal goal post theme member and between the right bottom horizontal goal post theme member and the central bottom horizontal goal post theme member.

The left bottom horizontal goal post theme member and the central bottom horizontal goal post theme member include connection channels for receiving fasteners for locking the left bottom horizontal goal post theme member and the central bottom horizontal goal post theme member together at adjusted positions.

The right bottom horizontal goal post theme member and the central bottom horizontal goal post theme member include connection channels for receiving fasteners for locking the right bottom horizontal goal post theme member and the central bottom horizontal goal post theme member together at adjusted positions. The upper left vertical goal post theme member and the lower left vertical goal post theme member include connection channels for receiving fasteners for locking the upper left vertical goal post theme member and the lower left vertical goal post theme member together at adjusted positions.

The upper right vertical goal post theme member and the lower right vertical goal post theme member include connection channels for receiving fasteners for locking the upper right vertical goal post theme member and the lower right vertical goal post theme member together at adjusted positions.

The left vertical goal post theme assembly includes a lower left vertical goal post theme member, and an upper left vertical goal post theme member is connected to the lower left vertical goal post theme member. Preferably, there is a telescopic connection between the upper left vertical goal post theme member and the lower left vertical goal post theme member.

The right vertical goal post theme assembly includes a lower right vertical goal post theme member, and an upper right vertical goal post theme member is connected to the lower right vertical goal post theme member. Preferably, there is a telescopic connection between the upper right vertical goal post theme member and lower right vertical goal post theme member.

The above brief description sets forth rather broadly the more important features of the present invention in order that the detailed description thereof that follows may be better understood, and in order that the present contributions to the art may be better appreciated. There are, of course, additional features of the invention that will be described hereinafter and which will be for the subject matter of the claims appended hereto.

In this respect, before explaining a preferred embodiment of the invention in detail, it is understood that the invention is not limited in its application to the details of the construction and to the arrangements of the components set forth in the following description or illustrated in the drawings. The invention is capable of other embodiments and of being practiced and carried out in various ways. Also, it is to be understood, that the phraseology and terminology employed herein are for the purpose of description and should not be regarded as limiting.

As such, those skilled in the art will appreciate that the conception, upon which disclosure is based, may readily be utilized as a basis for designing other structures, methods, and systems for carrying out the several purposes of the present invention. It is important, therefore, that the claims be regarded as including such equivalent constructions insofar as they do not depart from the spirit and scope of the present invention.

It is therefore an object of the present invention to provide a new and improved portable stand apparatus for an electronic display which has all of the advantages of the prior art and none of the disadvantages.

It is another object of the present invention to provide a new and improved portable stand apparatus for an electronic display which may be easily and efficiently manufactured and marketed.

It is a further object of the present invention to provide a new and improved portable stand apparatus for an electronic display which is of durable and reliable construction.

An even further object of the present invention is to provide a new and improved portable stand apparatus for an electronic display which is susceptible of a low cost of manufacture with regard to both materials and labor, and which accordingly is then susceptible of low prices of sale to the consuming public, thereby making such portable stand apparatus for an electronic display available to the buying public.

Still yet a further object of the present invention is to provide a new and improved stand apparatus for an electronic display which provides a portable stand for electronic display units, such as flat screen televisions.

Still another object of the present invention is to provide a new and improved portable stand apparatus for an electronic display that exhibits themes, such as sport themes, that are compatible with preferences of the viewers of the flat screen televisions.

Yet another object of the present invention is to provide a new and improved portable stand apparatus for an electronic display which exhibits themes of preferred football teams of the viewers.

Still yet another object is to provide a new and improved portable stand apparatus for an electronic display which presents a “football” theme preferred by many viewers, and which further provides a riser unit incorporated into the portable stand to simulate football goal posts characterized by a horizontal cross-bar and a pair of spaced uprights, which in turn provides an attractive eye-catching visual frame for the flat screen television display unit supported by the stand.

These together with still other objects of the invention, along with the various features of novelty which characterize the invention, are pointed out with particularity in the claims annexed to and forming a part of this disclosure. For a better understanding of the invention, its operating advantages and the specific objects attained by its uses, reference should be had to the accompanying drawings and descriptive matter in which there are illustrated preferred embodiments of the invention.

### BRIEF DESCRIPTION OF THE DRAWINGS

The invention will be better understood and the above objects as well as objects other than those set forth above will become more apparent after a study of the following detailed description thereof. Such description makes reference to the annexed drawing wherein:

FIG. 1 is a front view of a preferred embodiment of a portable stand apparatus for an electronic display unit, which includes a flat screen television thereon.

FIG. 2 is a side view of the embodiment of the invention shown in FIG. 1, taken along line 2-2 thereof.

FIG. 3 is a top view of the embodiment of the invention shown in FIG. 1, taken along line 3-3 thereof.

FIG. 4 is a bottom view of the embodiment of the invention shown in FIG. 1, taken along line 4-4 thereof.

FIG. 5 is an enlarged, partial rear view of the embodiment of the invention shown in FIG. 1, showing the support bracket assembly in detail.

FIG. 6 is a side view of the portion of the embodiment of the invention shown in FIG. 5, taken along line 6-6 thereof.

FIG. 7 is a top view of the portion of the embodiment of the invention shown in FIG. 5, taken along line 7-7 thereof.

FIG. 8 is a front view of an assembled assembly of football theme goal post members.

FIG. 9 is a side view of the assembly of football theme goal post members shown in FIG. 8, taken along line 9-9 thereof.

FIG. 10 is an elevated perspective view of the embodiment of the invention shown in FIG. 1.

### DESCRIPTION OF THE PREFERRED EMBODIMENT

With reference to the drawings, a new and improved portable stand apparatus for an electronic display embodying the principles and concepts of the present invention will be described.

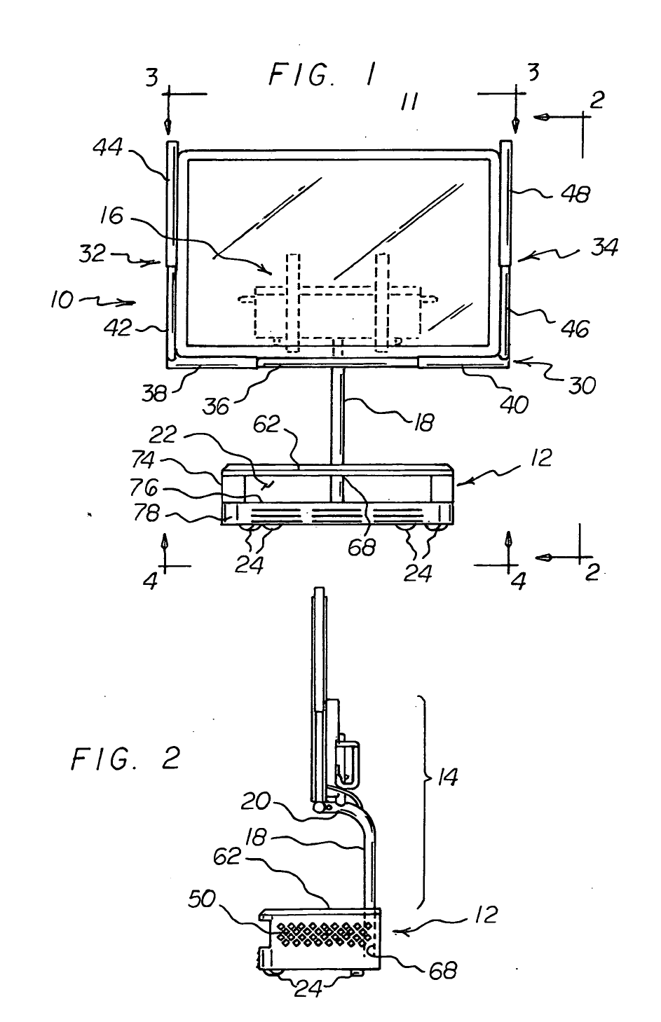

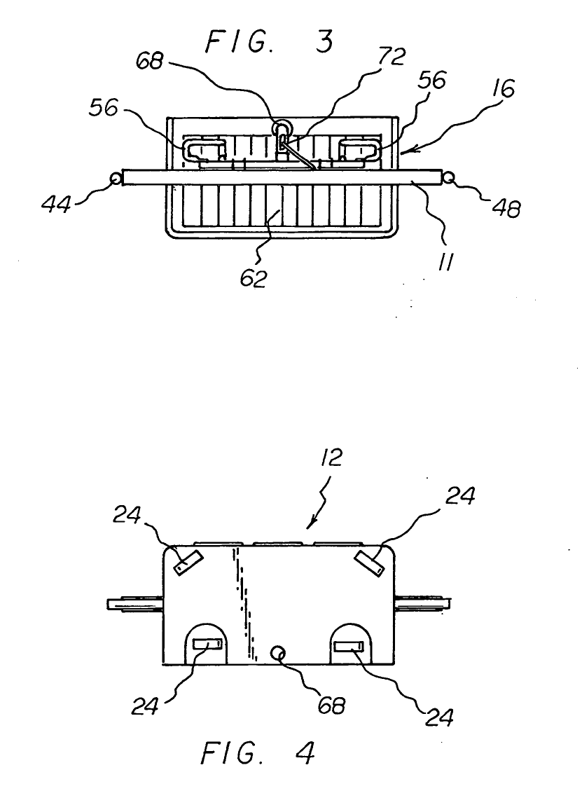

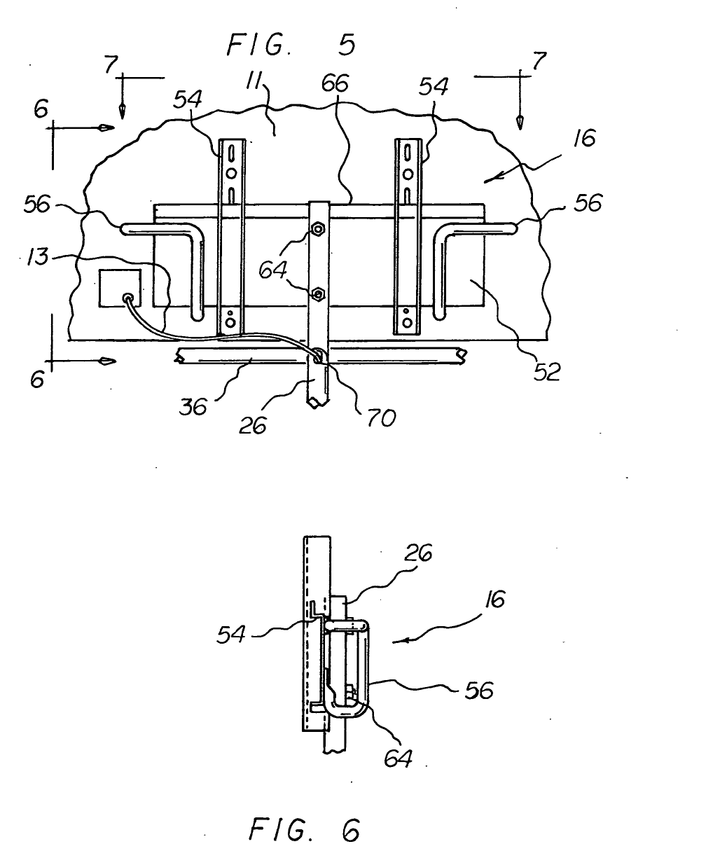

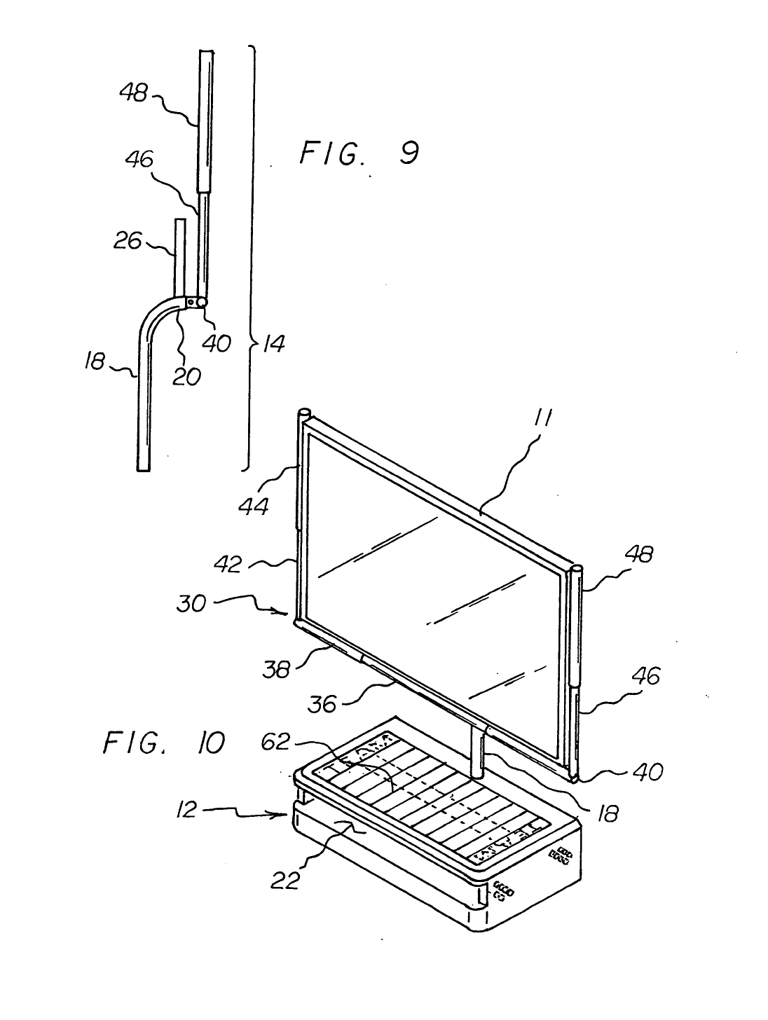

Turning to FIGS. 1-10, there is shown a preferred embodiment of the portable stand apparatus of the invention generally designated by reference numeral 10. The portable stand apparatus 10 is provided for an electronic display unit 11, such as a flat screen television. In each of the figures, reference numerals are shown that correspond to like reference numerals that designate like elements shown in other figures.

In the preferred embodiment, a portable stand apparatus 10 is provided for an electronic display unit 11, such as a flat screen television, and includes a base unit 12 and a riser unit 14 connected thereto. Riser-to-base connection means are connected to and supported by the base unit 12. A support bracket assembly 16 is interconnected between the electronic display unit 11 and the riser unit 14.

Preferably, the bottom of the base unit 12 has wheel assemblies 24, and the support bracket assembly 16 has handle members 56. The handle members 56 and the wheel assemblies 24 provide for easy portability and movability of the portable stand apparatus 10. In addition, the handle members 56 allow for easy mounting of the support bracket assembly 16 onto the flat screen television.

The base unit 12 can includes sides 74, an inside shelf 76, and skirts 78, all being connected together, such as by welding. Also the top portion 62 of the base unit 12 engages the sides 74 and can be welded to the sides 74.

The portable stand apparatus 10 can include a sport theme, a business theme, or a branding theme.

The riser-to-base connection means includes a riser-reception channel 68 for receiving the bottom portion of the riser unit 14. In addition, a cup can be welded to the bottom of the inside shelf 76 of the base unit 12 to receive the lower end of the first vertical riser portion 18 when the first vertical riser portion 18 is connected to the base unit 12. The sides 74, the inside shelf 76, and the skirts 78 can be made from sheet metal.

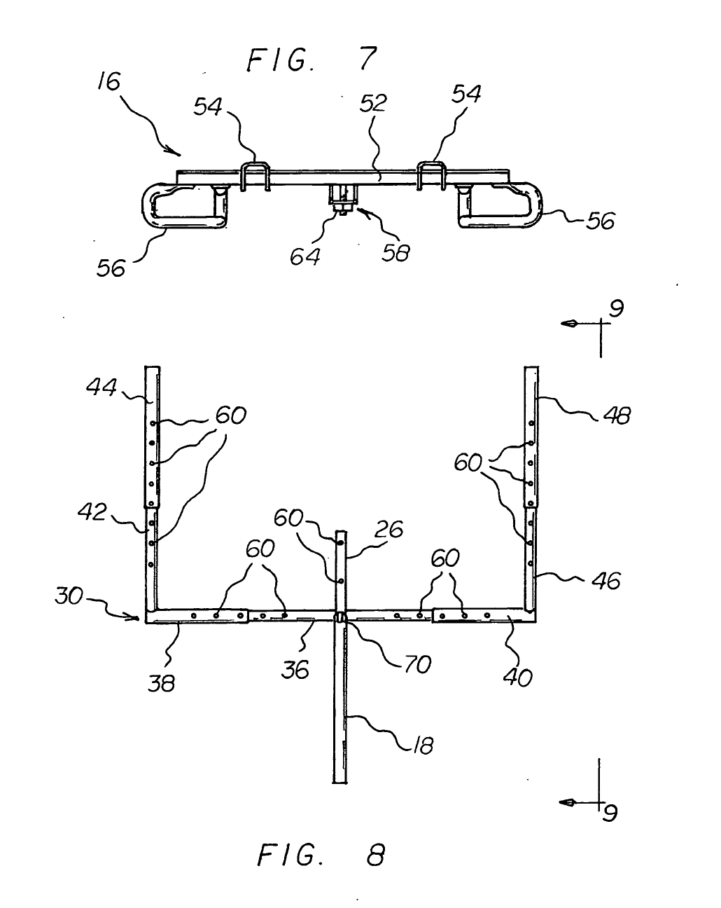

Preferably, as shown in detail in FIG. 7, the support bracket assembly 16 includes a support bracket base member 52. A pair of base-member-to-display connector members 54 is located on a first side of the support bracket base member 52 and are in sliding engagement with the support bracket base member 52. A base-member-to-riser-unit connector assembly 58 is connected to a second side of the support bracket base member 52, and a pair of handle members 56 is connected to the second side of the support bracket base member 52. The handle members 56 can be riveted to or otherwise rigidly attached to the support bracket base member 52.

Once the electronic display unit 11 is connected with the support bracket assembly 16, it will be appreciated that the handle members 56 can be used for facilitating lifting, pushing, or pulling of the portable stand apparatus 10 from one location to another location. The support bracket base member 52 includes a top portion 66 which engages the base-member-to-display connector members 54 for sliding engagement therewith.

The base-member-to-display connector members 54 can be slidingly adjusted along the top portion 66 of the support bracket base member 52, and the adjusted base-member-to-display connector members 54 are connected to appropriate locations on the electronic display unit 11. The support bracket assembly 16 can be employed as a universal mounting bracket for 32 inch to 60 inch flat screen televisions, for example.

Preferably, the electronic display unit 11 is a flat screen television. Alternatively, the electronic display unit 11 can be a laptop computer or a tablet computer, among other electronic display units.

Preferably, the riser unit 14 includes a first vertical riser portion 18 that is connected to and supported by the base unit 12. A horizontal riser portion 20 is connected to a top portion of the first vertical riser portion 18. The horizontal riser portion 20 extends from the first vertical riser portion 18 toward a front side of the base unit 12. A second vertical riser portion 26 is connected to the horizontal riser portion 20. The second vertical riser portion 26 can be is connected to the horizontal riser portion 20 by welding.

Preferably, the horizontal riser portion 20 extends from the first vertical riser portion 18 to approximately the middle of the base unit 12. This feature ensures stability and safety during movement or stationary use of the portable stand apparatus 10.

More specifically, the horizontal riser portion 20 can be formed as a curved degree transition member which includes a horizontal portion, a horizontal-to-vertical bend portion, and a vertical portion. In this respect, the curved degree transition member can be welded to the first vertical riser portion 18.

The second vertical riser portion 26 includes connection channels 60 for permitting connection of the support bracket assembly 16 to the second vertical riser portion 26 by employing fasteners 64, such as nuts and bolts. The fasteners can also be in the form of self-locking, spring-loaded buttons that extend through selected connection channels 60. It will be appreciated that by moving the support bracket assembly 16 upward or downward along the second vertical riser portion 26, prior to securing with fasteners 64, vertical adjustment of the flat screen television with respect to the portable stand apparatus 10 may be effected.

The electronic display unit 11 includes an electric power cord 13, and the second vertical riser portion 26 includes a first cord-reception channel 70 for receiving the electric power cord 13.

Preferably, the first vertical riser portion 18 is connected to and supported by the base unit 12 at an edge location in the base unit 12. In this respect, the bottom of the first vertical riser portion 18 can be fastened into a riser-reception channel 68 in the base unit 12. The base unit 12 includes an equipment storage chamber 22. The equipment that can be stored in the equipment storage chamber 22 can be used to store electronic control boxes, a cable box, video recorders, a power strip, and/or other miscellaneous items. The open equipment storage chamber 22 also gives access to AV hookups.

The plug for the electric power cord 13 can be plugged into an AC power outlet. Alternatively, the plug for the electric power cord 13 can be plugged into a power strip stored in the equipment storage chamber 22 in the base unit 12. The base unit 12 includes a second cord-reception channel 72 for receiving the electric power cord 13.

The wheel assemblies 24 that are connected to bottom portions of the base unit 12 can include swivel caster wheel assemblies each of which includes wheel locks, if desired.

The base unit 12 has a theme of a sport locker, and the base unit 12 also includes locker-inspired vents 50. The base unit 12 includes a selected sport theme. In this respect, the top portion 62 of the base unit 12 can include the selected sport theme thereon. The top portion 62 of the base unit 12 can be in the form of a thin planar overlay onto the top of the base unit 12. The thin planar overlay can be in the form of a removable pad, such as containing playing field graphics. Pads can be made of vinyl, rubber, paper, wood, glass, metals, etc., and can be related to any and all sports themes via suitable modifications. As depicted, the top portion 62 of the base unit 12 can include a football field theme.

The riser unit 14 includes the selected sport theme. The selected sport theme can be a football theme. In this respect, the riser unit 14 includes a center vertical football goal post theme. Other sport themes can include foul poles, hockey sticks, racing lights, and scoreboard features, etc.

A bottom horizontal goal post theme assembly 30 is connected to the riser unit 14 and includes a left vertical goal post theme assembly 32 and a right vertical goal post theme assembly 34. Each has a vertical goal post theme that is connected to respective ends of the bottom horizontal goal post theme assembly 30.

More specifically, the bottom horizontal goal post theme assembly 30 includes a central bottom horizontal goal post theme member 36. A left bottom horizontal goal post theme member 38 is connected to a left end of the central bottom horizontal goal post theme member 36, and a right bottom horizontal goal post theme member 40 is connected to a right end of the central bottom horizontal goal post theme member 36.

Preferably, there is a telescopic connection between the left bottom horizontal goal post theme member 38 and the central bottom horizontal goal post theme member 36 and between the right bottom horizontal goal post theme member 40 and the central bottom horizontal goal post theme member 36. More specifically, the central bottom horizontal goal post theme member 36 can be connected to the horizontal riser portion 20 such as by welding.

The left bottom horizontal goal post theme member 38 and the central bottom horizontal goal post theme member 36 include connection channels 60 for receiving fasteners 64 for locking the left bottom horizontal goal post theme member 38 and the central bottom horizontal goal post theme member 36 together at adjusted positions.

The right bottom horizontal goal post theme member 40 and the central bottom horizontal goal post theme member 36 include connection channels 60 for receiving fasteners 64 for locking the right bottom horizontal goal post theme member 40 and the central bottom horizontal goal post theme member 36 together at adjusted positions. The upper left vertical goal post theme member 44 and the lower left vertical goal post theme member 42 include connection channels 60 for receiving fasteners 64 for locking the upper left vertical goal post theme member 44 and the lower left vertical goal post theme member 42 together at adjusted positions.

The upper right vertical goal post theme member 48 and the lower right vertical goal post theme member 46 include connection channels 60 for receiving fasteners 64 for locking the upper right vertical goal post theme member 48 and the lower right vertical goal post theme member 46 together at adjusted positions.

The left vertical goal post theme assembly 32 includes a lower left vertical goal post theme member 42, and an upper left vertical goal post theme member 44 is connected to the lower left vertical goal post theme member 42. Preferably, there is a telescopic connection between the upper left vertical goal post theme member 44 and the lower left vertical goal post theme member 42.

The right vertical goal post theme assembly 34 includes a lower right vertical goal post theme member 46, and an upper right vertical goal post theme member 48 is connected to the lower right vertical goal post theme member 46. Preferably, there is a telescopic connection between the upper right vertical goal post theme member 48 and lower right vertical goal post theme member 46.

The connection between the left bottom horizontal goal post theme member 38 and the lower left vertical goal post theme member 42 and between the right bottom horizontal goal post theme member 40 and the lower right vertical goal post theme member 46 can be made by welding, by adhesives, or by fasteners 64.

If desired the lower left vertical goal post theme member 42 and the left bottom horizontal goal post theme member 38 can be formed as a unified, integrated structure. Also, if desired, the lower right vertical goal post theme member 46 and the right bottom horizontal goal post theme member 40 can be formed as a unified, integrated structure.

The flat screen television can be mounted on the portable stand apparatus 10 in an easy manner. First, the riser unit 14 is connected to the base unit 12. Second, the support bracket assembly 16 is connected to the flat screen television. Third, the support bracket assembly 16 is mounted on the second vertical riser portion 26 using fasteners 64 to secure the support bracket assembly 16 the second vertical riser portion 26.

After the flat screen television, the support bracket assembly 16, the riser unit 14, and the base unit 12 are assembled together, the goal post theme members are connected together and mounted to provide the goal post theme to the flat screen television.

More specifically, the left bottom horizontal goal post theme member 38 and the right bottom horizontal goal post theme member 40 are adjusted and secured to fit next to the bottom of the flat screen television.

In addition, the upper left vertical goal post theme member 44 and the lower left vertical goal post theme member 42 in addition to the upper right vertical goal post theme member 48 and lower right vertical goal post theme member 46 are adjusted to fit next to the left and right sides of the flat screen television, respectively.

It will thus be appreciated that in accordance with the invention, a portable stand apparatus for an electronic display (e.g. flat screen television) is provided which presents a “football” theme preferred by many viewers, and which further provides a riser unit incorporated into the portable stand to simulate “football goal posts” wherein the riser unit is characterized by a horizontal cross-bar and a pair of spaced uprights, which in turn provides an attractive eye-catching visual frame for the flat screen television display unit supported by the stand substantially as depicted in FIGS. 1 and 10.

It will further be appreciated that in accordance with the invention, the various simulated “football goal post” members or components 36, 40, 42, 44, 46 or 48 may suitably be telescopically adjusted relative to each other and then fastened in place in the adjusted position in order to fit the aforementioned attractive and eye-catching “football themed” frame to a flat television screen of selected size.

All of the goal post components can be powder-coated yellow color over metal tubing. All components of the support bracket assembly 16 can be powder-coated black color over metal parts. The base unit 12 can be powder-coated grey over metal parts.

As to the manner of usage and operation of the instant invention, the same is apparent from the above disclosure, and accordingly, no further discussion relative to the manner of usage and operation need be provided.

It is apparent from the above that the present invention accomplishes all of the objects set forth by providing a new and improved stand apparatus for an electronic display that is low in cost, relatively simple in design and operation, and which may advantageously be used as a portable stand apparatus for an electronic display which provides a portable stand for electronic display units, such as flat screen televisions. With the invention, a portable stand apparatus for an electronic display is provided which exhibits themes, such as sport themes, that are compatible with preferences of the viewers of the flat screen televisions. With the invention, a portable stand apparatus for an electronic display is provided which presents a “football” theme preferred by many viewers, and with the invention a portable stand apparatus for an electronic display is provided which provides a riser unit incorporated in the portable stand to simulate football goal posts characterized by a horizontal cross-bar and a pair of spaced uprights, which in turn provides an attractive eye-catching visual frame for the flat screen television display unit supported by the stand.

Thus, while the present invention has been shown in the drawings and fully described above with particularity and detail in connection with what is presently deemed to be the most practical and preferred embodiment(s) of the invention, it will be apparent to those of ordinary skill in the art that many modifications thereof may be made without departing from the principles and concepts set forth herein, including, but not limited to, variations in size, materials, shape, form, function and manner of operation, assembly and use.

Hence, the proper scope of the present invention should be determined only by the broadest interpretation of the appended claims so as to encompass all such modifications as well as all relationships equivalent to those illustrated in the drawings and described in the specification.

Finally, it will be appreciated that the purpose of the annexed Abstract is to enable the U.S. Patent and Trademark Office and the public generally, and especially the scientists, engineers and practitioners in the art who are not familiar with patent or legal terms or phraseology, to determine quickly from a cursory inspection the nature and essence of the technical disclosure of the application. Accordingly, the Abstract is neither intended to define the invention or the application, which only is measured by the claims, nor is it intended to be limiting as to the scope of the invention in any way.

What is claimed as being new and desired to be protected by Letters Patent of the United States is as follows:

1. A portable stand apparatus for an electronic display unit, comprising:
a base unit,
a riser unit
riser-to-base connection means connected to and supported by said base unit,
a support bracket assembly interconnected between the electronic display unit and said riser unit, and wherein at least the riser unit visually presents a sport theme.

2. The apparatus of claim 1 wherein said support bracket assembly includes:
a support bracket base member,
a pair of base-member-to-display connector members located on a first side of said support bracket base member and in sliding engagement with said support bracket base member,
a base-member-to-riser-unit connector assembly connected to a second side of said support bracket base member, and
a pair of handle members connected to said second side of said support bracket base member.

3. The apparatus of claim 1 wherein the electronic display unit is a flat screen television.

4. The apparatus of claim 1 wherein said riser unit includes:
a first vertical riser portion connected to and supported by said base unit,
a horizontal riser portion connected to a top portion of said first vertical riser portion, wherein said horizontal riser portion extends from said first vertical riser portion toward a front side of said base unit,
a second vertical riser portion connected to said horizontal riser portion, and
wherein said first vertical riser portion, said horizontal riser portion and said second vertical riser portion simulate corresponding portions of a football goal post assembly.

5. The apparatus of claim 4 wherein said horizontal riser portion extends to approximately half-way across said base unit from said first vertical riser portion and wherein said first vertical riser portion is connected to and supported by said base unit at an edge location on said base unit.

6. The apparatus of claim 1 wherein said base unit includes an equipment storage chamber.

7. The apparatus of claim 6 wherein said equipment storage chamber is located inside said base unit.

8. The apparatus of claim 1, further including:
wheel assemblies connected to bottom portions of said base unit.

9. The apparatus of claim 8 wherein said wheel assemblies include swivel caster wheel assemblies which include wheel locks.

10. The apparatus of claim 1 wherein said base unit presents an appearance simulating a sport locker.

11. The apparatus of claim 10 wherein said base unit also includes locker-inspired vents.

12. The apparatus of claim 10 wherein a top portion of said base unit includes a football field theme.

13. The apparatus of claim 4 wherein said horizontal riser includes:
a central bottom horizontal goal post theme member,
a left bottom horizontal goal post theme member connected to a left end of said central bottom horizontal goal post theme member, and
a right bottom horizontal goal post theme member connected to a right end of said central bottom horizontal goal post theme member, wherein there is a telescopic connection between said left bottom horizontal goal post theme member and said central bottom horizontal goal post theme member and between said right bottom horizontal goal post theme member and said central bottom horizontal goal post theme member.

14. The apparatus of claim 13 wherein said left bottom horizontal goal post theme member and said central bottom horizontal goal post theme member include connection channels for receiving fasteners for locking said left bottom horizontal goal post theme member and said central bottom horizontal goal post theme member together at adjusted positions.

15. The apparatus of claim 13 wherein said right bottom horizontal goal post theme member and said central bottom horizontal goal post theme member include connection channels for receiving fasteners for locking said right bottom horizontal goal post theme member and said central bottom horizontal goal post theme member together at adjusted positions.

16. The apparatus of claim 13, further including:
a left vertical goal post theme assembly and a right vertical goal post theme assembly, each having a vertical goal post theme, connected to respective ends of said bottom horizontal goal post theme assembly.

17. The apparatus of claim 16 wherein said left vertical goal post theme assembly includes:
a lower left vertical goal post theme member, and
an upper left vertical goal post theme member connected to said lower left vertical goal post theme member, wherein there is a telescopic connection between said upper left vertical goal post theme member and said lower left vertical goal post theme member.

18. The apparatus of claim 17 wherein said upper left vertical goal post theme member and said lower left vertical goal post theme member include connection channels for receiving fasteners for locking said upper left vertical goal post theme member and said lower left vertical goal post theme member together at adjusted positions.

19. The apparatus of claim 18 wherein said right vertical goal post theme assembly includes:
a lower right vertical goal post theme member, and
an upper right vertical goal post theme member connected to said lower right vertical goal post theme member, wherein there is a telescopic connection between said upper right vertical goal post theme member and lower right vertical goal post theme member.

20. The apparatus of claim 19 wherein said upper right vertical goal post theme member and said lower right vertical goal post theme member include connection channels for receiving fasteners for locking said upper right vertical goal post theme member and said lower right vertical goal post theme member together at adjusted positions.
